(19) United States
(12) Patent Application Publication
(10) Pub. No.: US 2026/0101820 A1
(43) Pub. Date: Apr. 9, 2026

(54) GROUND COVER STRUCTURE FOR A CHIP-TO-CHIP INTERCONNECTION

(71) Applicant: Cloud Light Technology Limited, Hong Kong (HK)

(72) Inventor: Ka Kit WONG, Birmingham (GB)

(21) Appl. No.: 19/204,082

(22) Filed: May 9, 2025

Related U.S. Application Data
(60) Provisional application No. 63/688,622, filed on Aug. 29, 2024.

(51) Int. Cl. H01L 23/00; H01L 25/065

(52) U.S. Cl. CPC H10W 90/00; H10W 72/5445; H10W 72/9445; H10W 90/753

(57) ABSTRACT

A device may include a first chip and a second chip, the first chip and the second chip being connected by a set of wirebonds. The device may include a ground cover structure providing a ground over the set of wirebonds. The ground cover structure may include a dielectric structure having a cavity on a first side of the dielectric structure. The ground cover structure may include a metal structure on a second side of the dielectric structure. The ground cover structure may include a dielectric material within the cavity of the dielectric structure.

Within the cavity, each wirebond in the set of wirebonds may be encapsulated by the dielectric material or by a combination of the dielectric material and the dielectric structure.

### CROSS-REFERENCE TO RELATED APPLICATION

This Patent Application claims priority to U.S. Provisional Ser. No. 63/688,622, filed on Aug. 29, 2024, and entitled “GROUND COVERED ARCHITECTURE WIRE-BONDING JOINT IN SEMICONDUCTORS. ” The disclosure of the prior Application is considered part of and is incorporated by reference into this Patent Application.

### TECHNICAL FIELD

The present disclosure relates generally to a chip-to-chip interconnection and to a ground cover structure for a chip-to-chip interconnection.

### BACKGROUND

A chip-to-chip interconnection is a component that provides an electrical connection between chips so as to enable communication between the chips (e.g., two chips assembled in a single module). The chips can be, for example, printed circuit board (PCB), PCB substrate, integrated circuits (IC), photonic IC, or another type of chip that requires a communication interconnection. It may be desirable for the chip-to-chip interconnection to provide an electrical connection that maximizes power transfer and ultra-high bandwidth transmission. A chip-to-chip interconnection can be provided using one or more separate components that provide a connection between pads on a pair of chips. The interconnection can be implemented using, for example, a high-speed architecture or high-density parallel architecture, which can be optimized to support multiple advanced two-dimensional (2D), two-and-a-half dimensional (2.5D), or three-dimensional (3D) packaging technologies. A chip-to-chip interconnection is an important structure of an industry trend in both monolithic system-on-chip (SoC) designs and multi-chip SoC designs. Such an approach mitigates concerns around high cost and low yield of small process nodes and provides additional product modularity and flexibility.

### SUMMARY

In some implementations, a device includes a first chip and a second chip, the first chip and the second chip being connected by a set of wirebonds; and a ground cover structure providing a ground over the set of wirebonds, the ground cover structure comprising: a dielectric structure having a cavity on a first side of the dielectric structure; a metal structure on a second side of the dielectric structure, and a dielectric material within the cavity of the dielectric structure, wherein, within the cavity, each wirebond in the set of wirebonds is encapsulated by the dielectric material or by a combination of the dielectric material and the dielectric structure.

In some implementations, a device includes a first chip and a second chip, the first chip and the second chip being connected by a set of wirebonds; and a ground cover structure providing a ground over the set of wirebonds, the ground cover structure comprising: a dielectric structure comprising a region that forms a cavity in the dielectric structure, wherein, a portion of each wirebond, in the set of wirebonds, that is within the cavity is encapsulated by a dielectric material or by a combination of the dielectric material and the dielectric structure, a metal structure on the dielectric structure, wherein the metal structure comprises a metal plane on the dielectric structure, an ohmic contact structure on the metal plane, and a wirebond on the ohmic contact structure, and the dielectric material within the cavity of the dielectric structure.

In some implementations, a device includes a first chip having a first set of bond pads and a second chip having a second set of bond pads, the first set of bond pads and the second set of bond pads being connected by a first set of wirebonds; a ground cover structure at least partially covering the first set of bond pads and the second set of bond pads, and providing a ground over the first set of wirebonds, wherein the ground cover structure comprises: a dielectric structure having a cavity, each wirebond in the first set of wirebonds being encapsulated by the dielectric material or by a combination of the dielectric material and the dielectric structure, and a metal structure; and a second set of wirebonds of that connect the first chip to the metal structure, wherein the second set of wirebonds is not covered by the ground cover structure.

### BRIEF DESCRIPTION OF THE DRAWINGS

FIGS. 1A-1C are diagrams illustrating examples of a device comprising a ground cover structure described herein.

FIG. 2 is a diagram illustrating an example implementation of the ground cover structure described herein.

FIG. 3 is a diagram illustrating an additional example implementation of the ground cover structure described herein.

FIGS. 4A-4B are diagrams illustrating additional example implementations of the ground cover structure described herein.

FIG. 5 is a diagram illustrating an example implementation of the device comprising mechanical supports as described herein.

### DETAILED DESCRIPTION

The following detailed description of example implementations refers to the accompanying drawings. The same reference numbers in different drawings may identify the same or similar elements.

A chip-to-chip interconnection may provide an electrical connection between a pair of chips (e.g., two chips assembled in a single module) so as to enable data communication between the chips. A chip-to-chip interconnection used in a given scenario may need to achieve a desired performance (e.g., with respect to impedance matching, resistive loss, shielding, or the like) while managing manufacturing challenges (e.g., with respect to alignment difficulty, rework difficulty, accommodation of a step between chips, accommodation of a tilt between chips, or the like). For example, as communications system utilization increases, it may be desirable to achieve performance of greater than 200 gigabits per lane with less than +/−10% capacitance mismatch, among other performance metrics.

One conventional chip-to-chip interconnection is a wirebond interconnection. A conventional wirebond interconnection comprises a group of wirebonds, with each wirebond connecting a different bond pad of a first chip and to a respective bond pad of a second chip. In the conventional wirebond interconnection, each wirebond is surrounded by air along most of its length, meaning that there exists an air gap between a given wirebond and other components in the environment. However, the conventional wirebond interconnection does not provide adequate capacitance compensation. In general, to provide capacitance compensation, a suitable reference ground plane and dielectric materials are needed. Capacitance compensation is a technique that can be used to achieve impedance matching by managing capacitive reactance so as to reduce or eliminate an impedance mismatch. As described herein, capacitance compensation may be determined with respect to signal transmission through wire bonds. Capacitance compensation is a technique that can be used to achieve impedance matching by managing capacitive reactance so as to reduce or eliminate an impedance mismatch. In general, an impedance mismatch can occur when a load impedance does not match a source or transmission line impedance. The impedance mismatch can cause reflection, energy loss, and a reduction of signal strength. At higher frequencies, capacitance can cause impedance to deviate from a desired level, which leads to a capacitive reactance that increases impedance mismatch. Capacitance compensation therefore involves counteraction of this unwanted capacitive reactance, an effect of which is to reduce or cancel out excess capacitive effect at some frequencies. Thus, by balancing inductance and capacitance (e.g., by selecting a capacitance value that corresponds to a selected inductance value and by selecting an inductance value that results in a corresponding capacitance value being within a range of achievable capacitance values), a desired impedance level can be achieved, thereby improving signal transmission in scenarios in which transmission speed is at 200 gigabits per lane or higher and/or in scenarios in which less than +/−10% (or +/−5 Ω) impedance mismatch is desirable, reducing or minimizing reflection, enabling increased and efficient power transfer, and reducing or minimizing signal loss. Additionally, or alternatively, balancing inductance and capacitance can achieve reduced variation in capacitance compensation.

In a conventional wirebond process, a ground reference is bond wire and the dielectric material is air, which cannot provide suitable impedance matching. Thus, although, the conventional wirebond interconnection is low cost, provides relatively easy alignment and reworkability, and can accommodate step and/or tilt between chips, the conventional wirebond interconnection suffers from poor impedance matching due to the high inductance of the wirebonds and lack of capacitance compensation. Further, resistive loss may be undesirable due to a length of the wirebonds (e.g., 300 micrometers (μm)).

Another conventional chip-to-chip interconnection is a direct flip-chip interconnection. According to a direct flip-chip interconnection technique, a first chip is arranged in a “flipped” position such that bond pads of the first chip are directly over bond pads of the second chip. A group of ball bumps are placed between bond pads of the first chip and bond pads of the second chip (e.g., such that a given ball bump is between a bond pad on the first chip and a respective bond pad on the second chip). A flip-chip interconnection achieves improved impedance matching and reduced resistive loss (e.g., as compared to a conventional wirebond interconnection). However, a flip-chip interconnection has a higher cost and a reduced manufacturability with respect to alignment, reworkability, and accommodation of a tilt between chips.

Still another conventional chip-to-chip interconnection is a silicon bridge interconnection. The silicon bridge interconnection uses a bridge structure comprising a group of routing elements (e.g., copper strips) formed in a dielectric material (e.g., silica). The bridge structure is formed so that, when arranged in a “flipped” position and placed over a first chip and a second chip, ball bumps connect ends of the routing elements to bond pads of the first chip and to bond pads of the second chip (e.g., such that a given bond pad of the first chip is connected to a respective bond pad of the second chip by one of the routing elements). A silicon bridge interconnection achieves improved impedance matching and reduced resistive loss (e.g., as compared to a conventional wirebond interconnection). However, a silicon bridge interconnection has a higher cost and a reduced manufacturability with respect to alignment, reworkability, and accommodation of a step or a tilt between chips.

Some implementations described herein provide techniques and apparatuses for a ground cover structure for a chip-to-chip interconnection. In some implementations, a device may include a first chip and a second chip, with the first chip and the second chip being electrically connected by a set of wirebonds. The device may further include a ground cover structure providing a ground over the set of wirebonds. In some implementations, the ground cover structure includes a dielectric structure having a cavity on a first side and a metal structure on a second side. The dielectric structure may further include a dielectric material within the cavity. Within the cavity, each wirebond in the set of wirebonds may be encapsulated by the dielectric material or by a combination of the dielectric material and the dielectric structure.

In some implementations, the metal structure of the ground cover structure provides capacitance compensation for the wirebonds, meaning that the ground cover structure provides improved impedance matching (e.g., as compared to a conventional wirebond interconnection). Impedance matching may refer to aligning electrical impedance of components to reduce reflections or maximize power transfer. Notably, impedance can be controlled based on wirebond height and/or a thickness of the dielectric structure in the ground cover structure. Additionally, the ground cover structure provides improved shielding without increasing resistive loss of the wirebonds. With respect to manufacturability, the ground cover structure supports easy alignment and accommodation of a step or a tilt between the chips. Additional details are provided below.

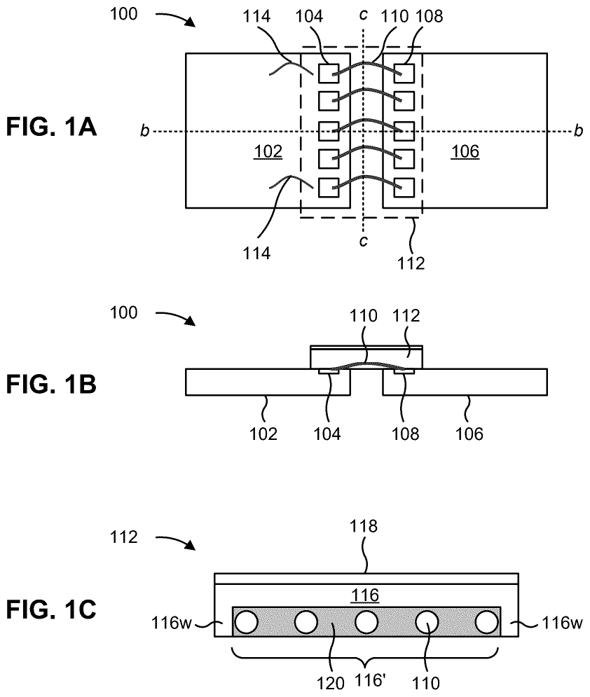

FIGS. 1A-1C are diagrams illustrating examples of a device 100 comprising a ground cover structure 112 described herein. FIG. 1A is an example of a top view of the device 100. FIG. 1B is a cross-section of the device 100 along the line labeled b-b in FIG. 1A. FIG. 1C is a cross-section of the ground cover structure 112 along the line labeled c-c in FIG. 1A. As shown in FIGS. 1A and 1B, the device 100 includes a first chip 102 comprising a set of bond pads 104 on a surface of the first chip 102, a second chip 106 comprising a set of bond pads 108 on a surface of the second chip 106, and a set of wirebonds 110 that connects the set of bond pads 104 of the first chip 102 to the set of bond pads 108 of the second chip 106 to form a chip-to-chip interconnection. As further shown, the device 100 may include a set of wirebonds 114 that connect the first chip 102 to the metal structure 118 of the ground cover structure 112, with the set of wirebonds 114 being outside of the ground cover structure 112. In some implementations, the set of wirebonds 114 may be inside or under the ground cover structure 112. In some implementations, the set of wirebonds 114 provides a ground connection to the metal structure 118. In some implementations, the chip-to-chip interconnection of the device 100 may support a high (e.g., 200 gigahertz (GHz) or above per lane) rate of communication with improved performance through improved impedance matching provided by tightly controlled capacitance compensation, as described below. In some implementations, the device 100 may achieve a target impedance value in a range of 75 ohms to 100 ohms. In some implementations, the device 100 may have a diameter, for the wirebonds 110, in a range of 0.8 millimeters to 1.2 millimeters. The target impedance may refer to a specific impedance value for a signal path that is a design goal to optimize signal quality across a system, accounting for losses, reflections, or other factors.

In some implementations, a dielectric constant, of the dielectric material 120, may be in a range of 2.5 to 5. In some implementations, a spacing between the wirebonds 110 and the ground cover structure 112 may be in a range of 50 micrometers to 500 micrometers. In some implementations, the set of bond pads 104 may have a size in a range of 100 micrometers to 125 micrometers and may have a square shape or a rectangular shape. In some implementations, a pitch between bond pads 104 may be in a range of 100 micrometers to 130 micrometers. In some implementations, a range of spacing between wirebonds 110 or bond pads 104 may be based on a dielectric constant of the dielectric material 120.

As further shown, the device 100 includes the ground cover structure 112, which provides a ground over the set of wirebonds 110 and facilitates capacitance compensation as described in further detail below. The capacitance compensation enables an improved wirebond interconnection, which is contrary to industry movement away from the use of wirebonds for chip-to-chip interconnection as lane rates increase. In some implementations, as illustrated in FIGS. 1A-1B, the ground cover structure 112 at least partially covers the set of bond pads 104 on the surface of the first chip 102 and the set of bond pads 108 on the surface of the second chip 106. Similarly, as illustrated in FIGS. 1A-1B, the ground cover structure 112 may cover a region of the surface of the first chip 102 (e.g., a region near the set of bond pads 104) and a region of the surface of the second chip 106 (e.g., region near the set of bond pads 108).

As shown in FIG. 1C, the ground cover structure 112 may include a dielectric structure 116 having a cavity 116′ on a first side of the dielectric structure 116 (e.g., a bottom side in FIG. 1C). The cavity 116′ is shown as filled (e.g., by dieletric material 120) in FIG. 1C. As further shown, the ground cover structure 112 may include a metal structure 118 on a second side of the dielectric structure 116 (e.g., a top side in FIG. 1C). In some implementations, a depth of the cavity 116′ (or a height of an interior region of the ground cover structure 112) may be related to a height of the set of wirebonds 110. That is, the depth of the cavity 116′ in the dielectric structure 116 may, in some implementations, be based on a height of the set of wirebonds 110 (e.g., so as to control a height of the set of wirebonds 110 with respect to a surface of the first chip 102 or a surface of the second chip 106). In some implementations, as illustrated in FIG. 1C, the ground cover structure 112 comprises a plurality of wall regions 116w surrounding the cavity 116′. In some implementations, the plurality of wall regions 116w may provide mechanical support for the ground cover structure 112.

As shown, the dielectric structure 116 may comprise a dielectric material 120 within the cavity 116′ of the dielectric structure 116. As shown, each wirebond 110 in the set of wirebonds 110 may be encapsulated within the cavity 116′ by the dielectric material 120 or by a combination of the dielectric material 120 and the dielectric structure 116 (e.g., when a portion of a given wirebond 110 is in contact with a surface of the dielectric structure 116 within the cavity 116′ such that no dielectric material 120 is between the portion of the given wirebond 110 and the surface of the cavity 116′). In some implementations, the dielectric material 120 provides capacitance compensation. In a conventional wirebond interconnection, a set of wirebonds is surround by air, which has a dielectric constant of approximately 1.0. However, the dielectric constant of air is insufficient to serve as a compensation capacitor in the cavity 116′. Thus, in the device 100, the cavity 116′ is filled with the dielectric material 120, with the dielectric material 120 having a dielectric constant that is greater than 1.0. In some implementations, the dielectric constant of the dielectric material 120 may be in a range from approximately 2.5 to approximately 5.0. Notably, the dielectric constant of the dielectric material 120 may be an arbitrary value (e.g., less than 2.5 or greater than 5.0) and may still be sufficient to provide a desired impedance matching with appropriate design of the device 100. In some implementations a target impedance range is within +/−10% of a configured impedance value. In some implementations an amount of reflection is approximately less than −10 decibels. In some implementations, the dielectric material 120 may comprise an epoxy, a resin, a paste, a gel, or another suitable material. Notably, the difference between an epoxy or resin and a paste or gel is that the epoxy or resin may have a solid form (e.g., rather than a milky form or liquid form as in the case of a paste or gel). A dielectric material 120 having a solid form may be advantageous when a temperature of the device 100 is expected to be relatively hot (e.g., in a range from approximately 70 degrees Celsius (°C) to approximately 90° C.) and the device 100 is exposed to vibration during normal operation. A dielectric material 120 with a milky or liquid form that is sufficiently viscous at high temperatures and under vibration so as to remain in place during operation can be used in some implementaions, in which case reliability may be increased.

In some implementations, a portion of one or more wirebonds 110 in the set of wirebonds 110 may be in contact with a surface of the cavity 116′ in the dielectric structure 116. In such an implementation, the wirebond 110 may be encapsulated by a combination of the dielectric material 120 and the dielectric structure 116 (e.g., rather than being surrounded by only the dielectric material 120). Such an implementation may be used to, for example, control a height of the wirebonds 110 so as to reduce impedance variation along a length of the wirebond 110, which improves control of capacitance compensation provided by the ground cover structure 112.

In some implementations, the ground cover structure 112 provides capacitance compensation to a transmission line of the device 100. For example, a wirebond 110 in the set of wirebonds 110 may form part of the transmission line of the device 100. This enables an improved wirebond interconnection, thereby enabling use of wirebond interconnection for high-speed and/or low impedance operations for which chip-to-chip interconnection has been proposed. In some implementations, the ground cover structure 112 (e.g., a combination of the dielectric structure 116, the metal structure 118, and/or the dielectric material 120) provide capacitance compensation for the device 100. In some implementations, the capacitance compensation provided by the ground cover structure 112 is defined by one or more characteristics of the dielectric structure 116, such as a thickness of a region of the dielectric structure 116 between the cavity 116′ and the metal structure 118, a depth of the cavity 116′ in the dielectric structure 116, a distance between the metal structure 118 and one or more wirebonds 110 (e.g., as defined by the cavity depth), a material type of the dielectric structure 116, or a material type of the dielectric material 120. Notably, any one or more of these characteristics of the dielectric structure 116 may be selected so as to achieve a desired capacitance compensation and in order to improve impedance matching for the device 100. For example, when an inductance of a bondwire is high (e.g., a diameter thereof is small), a higher capacitance may be selected for compensation. Further, a dielectric thickness or dielectric constant may be controlled to achieve the higher capacitance that is selected.

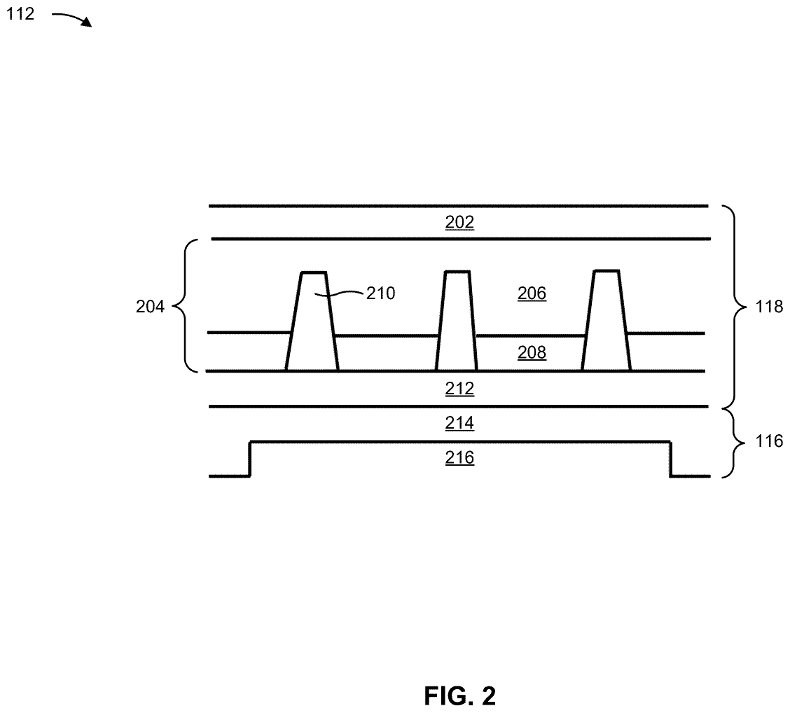

Further, in some implementations, a diameter of the wirebonds 110 can be selected or adjusted in association with achieving a target impedance. In some implementations, selection of the diameter of the wirebonds 110 can be used to control or adjust inductance of the transmission line. Thus, one or more characteristics of the ground cover structure 112 and/or the wirebonds 110 can be selected to provide capacitance compensation that serves to reduce or minimize reflection, enable increased and efficient power transfer, and reduce or minimize signal loss, thereby improving performance of the device 100 (e.g., as compared to a conventional wirebond interconnection). For example, characteristics may include a target impedance in range of 75 ohms to 100 ohms, a bondwire diameter in a range of 0.8 millimeters to 1.2 millimeters, a dielectric constant in a range of 2.5 to 5, or a bondwire to ground cover structure spacing in a range of 50 micrometers to 500 micrometers. FIGS. 2, 3, and 4A-4B described below provide various example implementations of the ground cover structure 112.

In some implementations, the metal structure 118 of the ground cover structure 112 provides capacitance compensation for the wirebonds 110, meaning that the ground cover structure 112 provides improved impedance matching (e.g., as compared to a conventional wirebond interconnection). Further, the ground cover structure 112 provides improved shielding without increasing resistive loss of the wirebonds 110. Additionally, with respect to manufacturability, the ground cover structure 112 supports easy alignment and accommodation of a step or a tilt between the first chip 102 and the second chip 106.

Notably, the device 100 provides an improved wirebond interconnection, which is contrary to industry movement away from the use of wirebonds for chip-to-chip interconnection as line rates increase. In this way, the device 100 maintains the relatively low cost and simplicity of a wirebond interconnection (e.g., as compared to a flip-chip interconnection or a silicon bridge interconnection), while achieving improved performance.

As indicated above, FIGS. 1A-1C are provided as examples. Other examples may differ from what is described with regard to FIGS. 1A-1C.

FIG. 2 is a diagram illustrating an example implementation of a ground cover structure 112 described herein. In FIG. 2, the cavity 216, in which wirebonds 110 may be located, is illustrated below the etched dielectric layer 214. In the example implementation shown in FIG. 2, a semiconductor IC process is used to form the ground cover structure 112. As shown, a ground cover structure 112 formed using a semiconductor IC process may include a metal structure 118 comprising a wirebond plane 202, an ohmic contact structure 204 (including a doped semiconductor layer 206, a dielectric layer 208, and a set of vias 210), and a metal plane layer 212, and a dielectric structure 116 comprising an etched dielectric layer 214.

In some implementations, with reference to FIG. 2, the etched dielectric layer 214 (e.g., an oxide layer, such as silicon dioxide or another oxide selected to achieve a particular dielectric constant (with an epoxy dielectric constant) to achieve a particular performance metric) may comprise a dielectric layer that is etched in to form a cavity 216 (e.g., a silicon structure). In such an implementation, a depth of the cavity 216 is based on an etch depth associated with forming the etched dielectric layer 214. In some implementations, the depth of the cavity 216 and, therefore, a thickness of the region of the etched dielectric layer 214 between the cavity 216 and the metal plane layer 212 is controllable to a high precision (e.g., less than approximately 5 micrometer (μm) precision or less than approximately 1 μm precision). The depth of cavity 216 provides a height control for the set of wirebonds 110, which may be disposed close to a surface of the cavity 216 (e.g., based on a thickness of the dielectric layer 214). The high precision of the thickness of the dielectric layer 214 enables significantly improved control of a position and height of the set of wirebonds 110, thereby enabling impedance matching performance and, furthermore, reduces or minimizes variation in mass production of the ground cover structure 112, which reduces yield loss. Further, in some implementations, the depth of the cavity 216 may be used to provide height control of the set of wirebonds 110.

As indicated above, FIG. 2 is provided as an example. Other examples may differ from what is described with regard to FIG. 2.

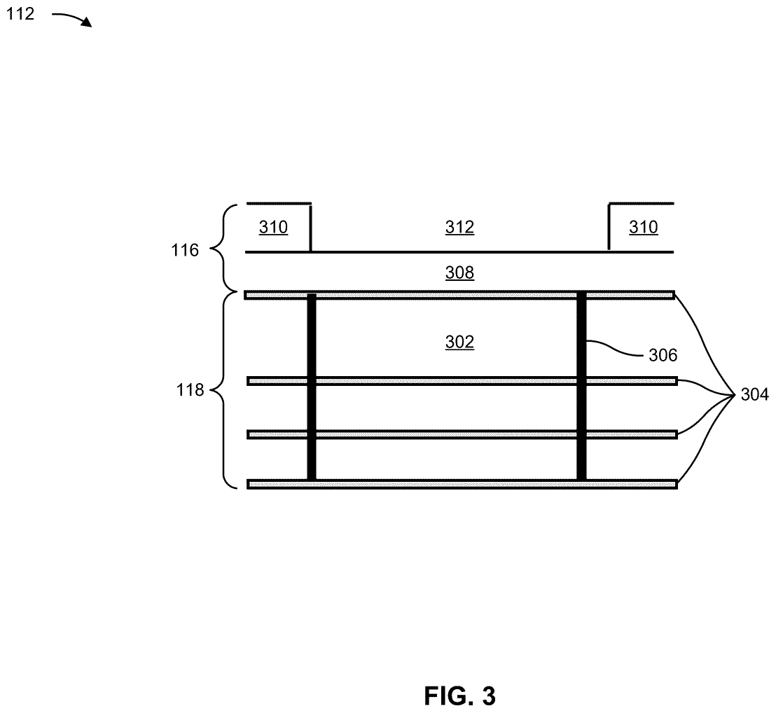

FIG. 3 is a diagram illustrating an additional example implementation of the ground cover structure 112 described herein. In the example implementation shown in FIG. 3, the ground cover structure 112 comprises a cavity substrate, illustrated upside down, where cavity 312 is in the same context as cavity 216 in FIG. 2. In some implementations, the cavity substrate may be formed using a PCB fabrication process. As shown in FIG. 3, a ground cover structure 112 in the form of a cavity substrate may include a metal structure 118 comprising a core layer 302 comprising a set of metal ground plane layers 304 connected by vias 306, and a dielectric structure 116 comprising a first dielectric layer 308 and a second dielectric layer 310. In such an implementation, a cavity 312 is defined by the second dielectric layer 310. Thus, a depth of the cavity 312 is defined by a thickness of the second dielectric layer 310.

In some implementations, the depth of the cavity 312 is controllable to a precision in a range from approximately 10 μm to approximately 20 μm precision or a range from approximately 25 μm to approximately 50 μm precision. Such a degree of precision of the depth of the cavity 312 results in improved precision in a position and size of the wirebonds 110 (e.g., relative to the metal structure 118), thereby enabling improved impedance matching performance (e.g., as compared to a conventional wirebond interconnection) while achieving a relatively low-cost ground cover structure 112 (e.g., in connection with having a particular material selected for the dielectric layer 308 and/or the dielectric layer 310). An absence of the ground cover structure 112 may result in impedance being greater than a threshold value (e.g., and outside of a range of +/−10% of a configured value), which could result in degraded signal performance and communication errors.

As indicated above, FIG. 3 is provided as an example. Other examples may differ from what is described with regard to FIG. 3.

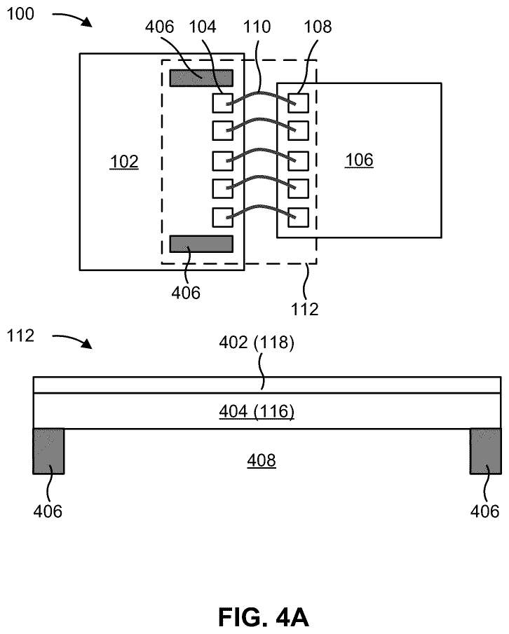

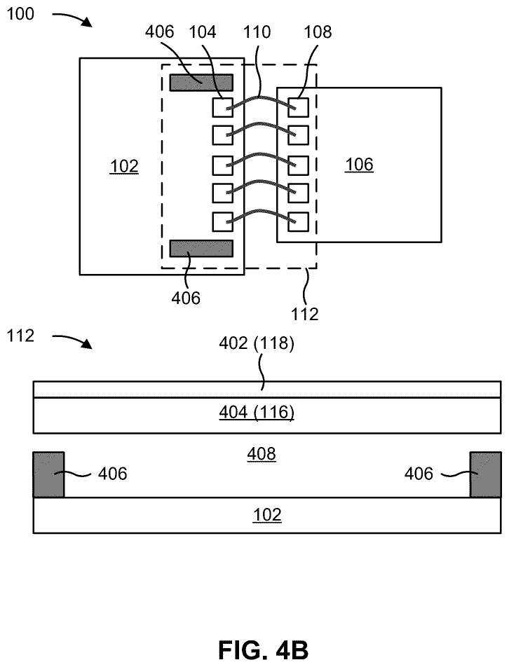

FIGS. 4A-4B are diagrams illustrating additional example implementations of the ground cover structure 112 described herein. In the example implementations shown in FIGS. 4A and 4B, the ground cover structure 112 comprises a flat substrate with a set of thin film adhesive regions. As shown in FIGS. 4A and 4B, a ground cover structure 112 in the form of a flat substrate with a set of thin film adhesive regions substrate may include a metal structure 118 comprising a metal plane 402 and a dielectric structure 116 comprising a flat substrate 404 and a set of thin film adhesive regions 406. In some other implementations described herein, a layer of a flat substrate material (e.g., copper, aluminum, or an under-bump metallization (UBM) material, among other examples) with a layer of insulation can be provided. In some implementations, as illustrated in FIG. 4A, the set of thin film adhesive regions 406 may be first affixed to the flat substrate 404, and a resulting ground cover structure 112 may be affixed to the first chip 102. Alternatively, as illustrated in FIG. 4B, the set of thin film adhesive regions 406 may be first affixed to the first chip 102, and the resulting structure may then be affixed to the flat substrate 404 to form the ground cover structure 112. In some implementations, a cavity 408 is defined by a thickness of the set of thin film adhesive regions 406. Thus, a depth of the cavity 408 is defined by a thickness of the set of thin film adhesive regions 406. Wirebonds 110 may be located inside of cavity 408.

In some implementations, the depth of the cavity 408 is controllable to a precision in a range from approximately 30 μm to approximately 50 μm precision or a range of 50 μm precision to 300 μm precision. Such a degree of precision of the depth of the cavity 312 enables improved impedance matching performance (e.g., as compared to a conventional wirebond interconnection) while achieving a low-cost ground cover structure 112.

As indicated above, FIGS. 4A-4B are provided as examples. Other examples may differ from what is described with regard to FIGS. 4A-4B.

In some implementations, a portion of one or more wirebonds 110 in the set of wirebonds 110 may be in contact with a surface of the cavity in the dielectric structure 116, as described above. In such an implementation, the pressure of the ground cover structure 112 on the wirebond 110 exert force sufficient to damage or even shear a bonding location of the wirebond 110. To address this issue, in some implementations, the device 100 may include mechanical supports to strengthen the connection of the wirebond 110.

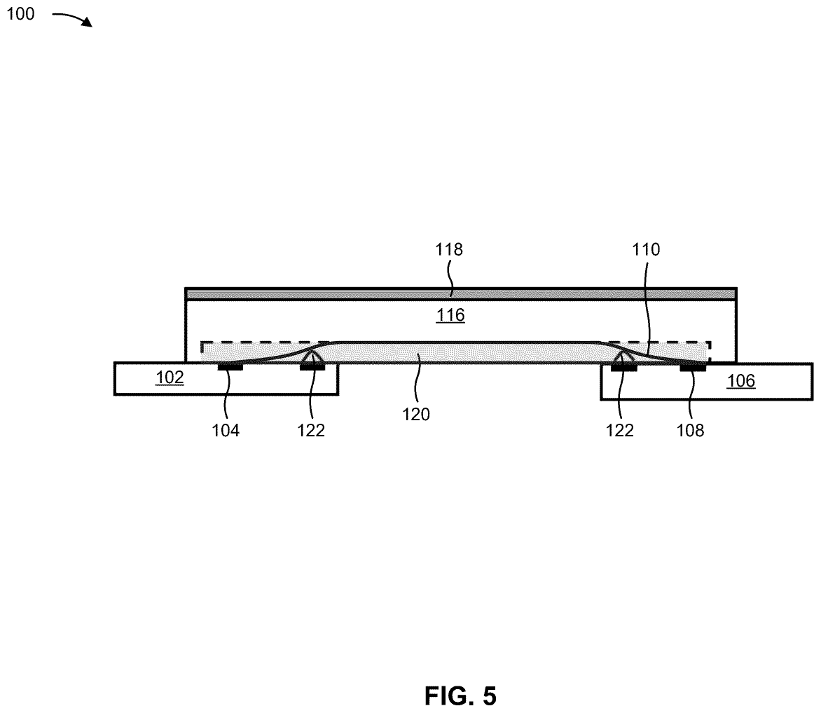

FIG. 5 is a diagram illustrating an example implementation of the device 100 comprising mechanical supports as described herein. As shown in FIG. 5, the device 100 may include a first mechanical support 122 for affixing a wirebond 110 to the first chip 102 and a second mechanical support 122 for affixing the wirebond 110 to the second chip 106.

In some implementations, a mechanical support 122 may be formed by adding solder (e.g., using a solder paste process) and performing a reflow. In some implementations, a height of the solder associated with the mechanical support may be controlled by a thickness of the solder paste and an open area of a solder mask. Here, when the ground cover structure 112 is pressed into position over the first chip 102 and the second chip 106, some portion of the external force is provided to the mechanical support 122 (rather than a bonding location on a bond pad 104 or a bond pad 108). In this way, the connection of the wirebond 110 can be protected, thereby improving reliability and reducing a likelihood of wirebond connection failure. Further, in some implementations, the ground cover structure 112 can be used to flatten a portion of the wirebond 110 so as to reduce impedance variation along the wirebond, as described above.

As indicated above, FIG. 5 is provided as an example. Other examples may differ from what is described with regard to FIG. 5.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A device, comprising:
a first chip and a second chip, the first chip and the second chip being connected by a set of wirebonds; and
a ground cover structure providing a ground over the set of wirebonds, the ground cover structure comprising:
a dielectric structure having a cavity on a first side of the dielectric structure,
a metal structure on a second side of the dielectric structure, and
a dielectric material within the cavity of the dielectric structure,
wherein, within the cavity, each wirebond in the set of wirebonds is encapsulated by the dielectric material or by a combination of the dielectric material and the dielectric structure.

2. The device of claim 1, wherein the dielectric structure comprises an etched dielectric layer, wherein a depth of the cavity is based on an etch depth associated with forming the etched dielectric layer.

3. The device of claim 1, wherein the metal structure comprises a metal plane, an ohmic contact structure on the metal plane, and a wirebond plane on the ohmic contact structure.

4. The device of claim 1, wherein the dielectric structure comprises a first dielectric layer and a second dielectric layer on the first dielectric layer, wherein a depth of the cavity is based on a thickness of the second dielectric layer.

5. The device of claim 1, wherein the metal structure comprises a core layer comprising one or more metal ground plane layers.

6. The device of claim 1, wherein the dielectric structure comprises a dielectric layer and a set of thin film adhesive regions on the dielectric layer, wherein a depth of the cavity is based on a thickness of the thin film adhesive regions.

7. The device of claim 1, wherein the metal structure comprises a metal plane layer.

8. The device of claim 1, wherein the dielectric material comprises an epoxy or a resin.

9. The device of claim 1, wherein a portion of a wirebond, in the set of wirebonds, is in contact with a surface of the cavity.

10. The device of claim 1, wherein the device comprises a first mechanical support for affixing a wirebond, of the set of wirebonds, to the first chip and a second mechanical support for affixing the wirebond to the second chip.

11. The device of claim 1, wherein the ground cover structure at least partially covers a first set of bond pads on a surface of the first chip and a second set of bond pads on a surface of the second chip.

12. The device of claim 1, wherein the ground cover structure covers a first region of a surface of the first chip and a second region of a surface of the second chip.

13. The device of claim 1, wherein the ground cover structure comprises a plurality of wall regions surrounding the cavity, where one or more wall regions of the plurality of wall regions provide mechanical support for the ground cover structure.

14. The device of claim 1, wherein the first chip is connected to the metal structure by a second set of wirebonds, where the second set of wirebonds is outside of the ground cover structure.

15. The device of claim 1, wherein a depth of the cavity or a height of an interior region of the ground cover structure is related to a height of the set of wirebonds.

16. A device, comprising:
a first chip and a second chip, the first chip and the second chip being connected by a set of wirebonds; and
a ground cover structure providing a ground over the set of wirebonds, the ground cover structure comprising:
a dielectric structure comprising a region that forms a cavity in the dielectric structure,
wherein, a portion of each wirebond, in the set of wirebonds, that is within the cavity is encapsulated by a dielectric material or by a combination of the dielectric material and the dielectric structure,
a metal structure on the dielectric structure, wherein the metal structure comprises a metal plane on the dielectric structure, an ohmic contact structure on the metal plane, and a wirebond on the ohmic contact structure, and
the dielectric material within the cavity of the dielectric structure.

17. The device of claim 16, wherein the ground cover structure at least partially covers a first set of bond pads on a surface of the first chip and a second set of bond pads on a surface of the second chip.

18. The device of claim 16, wherein the ground cover structure covers a first region of a surface of the first chip and a second region of a surface of the second chip.

19. The device of claim 16, wherein the ground cover structure comprises a plurality of wall regions surrounding the cavity, where one or more wall regions of the plurality of wall regions provide mechanical support for the ground cover structure.

20. A device, comprising:
a first chip having a first set of bond pads and a second chip having a second set of bond pads, the first set of bond pads and the second set of bond pads being connected by a first set of wirebonds;
a ground cover structure at least partially covering the first set of bond pads and the second set of bond pads, and providing a ground over the first set of wirebonds, wherein the ground cover structure comprises:
a dielectric structure having a cavity, each wirebond in the first set of wirebonds being encapsulated by a dielectric material or by a combination of the dielectric material and the dielectric structure, and
a metal structure; and
a second set of wirebonds of that connect the first chip to the metal structure, wherein the second set of wirebonds is not covered by the ground cover structure.
